(19) United States
(12) Patent Application Publication
(10) Pub. No.: US 2025/0125589 A1
(43) Pub. Date: Apr. 17, 2025

(54) COMPONENT HAVING IMPROVED PROPERTIES WITH REGARD TO WAVELENGTH BROADENING

(71) Applicant: ams-OSRAM International GmbH, Regensburg (DE)

(72) Inventors: Sebastian SCHLEGL, Bad Abbach (DE); André SOMERS, Obertraubling (DE); Jörg Erich SORG, Regensburg (DE)

(73) Assignee: ams-OSRAM International GmbH, Regensburg (DE)

(21) Appl. No.: 18/567,567

(22) PCT Filed: Jun. 9, 2022
(86) PCT No.: PCT/EP2022/065698

§ 371 Date: Dec. 6, 2023

(30) Foreign Application Priority Data
Jun. 11, 2021 (DE) 10 2021 115 230.5
Sep. 6, 2021 (DE) 10 2021 123 010.1

(51) Int. Cl. H01S 5/40; H01S 5/02315

(52) U.S. Cl. CPC H01S 5/4056; H01S 5/02315

(57) ABSTRACT

A component including a carrier and exactly two semiconductor chips arranged next to one another on the carrier is specified, the exactly two semiconductor chips are each embodied as a double-emitter having exactly two emitter regions or each being embodied as a triple-emitter having exactly three emitter regions and are thus different from a single-emitter. The emitter regions of the component are assigned to the exactly two semiconductor chips, the exactly two semiconductor chips being laser diodes which each have ridges defining the emitter region. The exactly two semiconductor chips are electrically contacted via the carrier.

### CROSS-REFERENCE TO RELATED APPLICATIONS

The present application is a national stage entry from International Application No. PCT/EP2022/065698, filed on Jun. 9, 2022, published as International Publication No. WO 2022/258757 A1 on Dec. 15, 2022, and claims priority to German Patent Application Nos. 10 2021 115 230.5, filed Jun. 11, 2021, and 10 2021 123 010.1, filed on Sep. 6, 2021, the disclosures of all of which are hereby incorporated by reference in their entireties.

### FIELD

A component is specified.

### BACKGROUND

In diffractive waveguides, the bandwidth of the laser beam plays a decisive role. Due to small bandwidth of a single laser, optically visible artifacts are formed in the waveguide. These are visible and disturbing for the user of AR (augmented reality) or VR (virtual reality) glasses or data glasses.

By shifting individual emitter regions of a quadruple-emitter by about a few nanometers, for example by 2.5 nm, the bandwidth broadening can be adjusted. However, this method is very complex in the manufacture and leads to high yield losses.

One object is to provide a component having improved properties with regard to wavelength broadening, in particular for increasing the image quality of, for example, AR glasses or VR glasses or data glasses.

This object is solved by a component according to the independent claim. Further designs and further developments of the component are the subject matter of the dependent claims.

### SUMMARY

By an adapted chip design, a multiple-emitter, for example a quadruple-emitter, can be divided into small emitters, for example into two double-emitters. Compared to the multiple-emitter, the distance between the emitter regions can be maintained. The division into two laser diodes leads to a much simplified production process and thus gives a simpler method to extend the bandwidth especially to 10 nm, for example to 10 nm+/−5 nm, 10 nm+/−3 nm, 10 nm+/−3 nm or 10 nm+/−1 nm for reducing optical artifacts in the waveguide.

In at least one embodiment of a component, it has a plurality of emitter regions. In particular, the emitter regions are assigned to at least or exactly two semiconductor chips.

In at least one embodiment of a component, it has at least two semiconductor chips. The two semiconductor chips are in particular two emitters or two laser diodes. In particular, the emitters or laser diodes are different from a single-emitter. The semiconductor chips may be double-emitters or triple-emitters. For example, the semiconductor chips may have two or three ridges. The semiconductor chips of the component may be arranged side by side on a carrier. If the semiconductor chip has two ridges, it is referred to as a dual or double-emitter.

In at least one further embodiment of a component, the latter has a carrier and exactly two semiconductor chips arranged next to one another on the carrier. The exactly two semiconductor chips are formed in each case as double-emitters with exactly two emitter regions or in each case as triple-emitters with exactly three emitter regions and are thus different from a single-emitter. The emitter regions, for instance all emitter regions, of the component are assigned to the exactly two semiconductor chips. The exactly two semiconductor chips are laser diodes, each having ridges, wherein the ridges define the emitter regions. The exactly two semiconductor chips are electrically contacted via the carrier.

In particular, the emitter regions are defined by so-called ridge regions, or ridges. A component or semiconductor chip having such ridge regions is also referred to as a ridge laser or a stripe laser. Such a component or semiconductor chip may have one or more stripe waveguides formed in a second half-waveguide region of the respective semiconductor chip. Such strip waveguide may be formed for one-dimensional wave-guiding along a wave-guiding direction of a laser radiation generated in an active region of the semiconductor chip. If the semiconductor chip has two or more emitter regions, the semiconductor chip may have two or more such strip waveguides.

For example, the emitter region or strip waveguide extends along a lateral direction of the semiconductor chip. In particular, the strip waveguide is in the form of a ridge projecting along a vertical direction. If the semiconductor chip has a plurality of emitter regions, the semiconductor chip may have, in top view, a plurality of strip waveguides arranged side by side, in particular in the form of protruding ridges arranged side by side.

A lateral direction is understood to mean a direction which is in particular parallel to a main extension surface of the semiconductor chip or of the carrier. A vertical direction is understood to mean a direction which is directed in particular perpendicularly to the main extension surface of the semiconductor chip or of the carrier. The vertical direction and the lateral direction are orthogonal to each other.

In case of a ridge laser or a stripe laser, laser beams are coupled out at a side surface of the ridge laser or of the stripe laser. The generated laser beams propagate essentially along a lateral direction parallel to the strip waveguide.

According to at least one embodiment of the component, the semiconductor chips of the component have connection pads. Via the connection pads, the semiconductor chips or the emitters can be contacted externally, for example via a contact structure of the carrier.

In particular, the connection pads are located on a rear side of the semiconductor chip. For example, the connection pads are arranged between the carrier and a semiconductor body of the semiconductor chip. The semiconductor chip can have through-contacts which extend along the vertical direction, for example through at least one semiconductor region of the semiconductor body, and are each electrically conductively connected to one of the connection pads.

According to at least one embodiment of the component, the semiconductor chips are electrically connected via the carrier. For example, the carrier has a contact structure being in electrical contact with the connection pads of the semiconductor chip. The contact structure may be in electrical contact with all connection pads of the semiconductor chips.

According to at least one embodiment of the component, the number of connection pads of a semiconductor chip or of an emitter is equal to the number of ridges or emitter regions of the associated semiconductor chip or emitter.

According to at least one embodiment of the component, the latter has at least two, in particular exactly two double-emitters or triple-emitters.

According to at least one embodiment of the component, the emitters are arranged adjacent to each other such that a wavelength broadening of 10 nm+/−5 nm, 10 nm+/−3 nm, or 10 nm+/−1 nm is achieved.

In at least one embodiment of AR-, VR-, or data glasses, the glasses include the component described herein.

### BRIEF DESCRIPTION OF THE DRAWINGS

Further embodiments and further developments of the component are apparent from the exemplary embodiments explained below in connection with FIGS. 1 to 5.

FIG. 1 shows a conventional component with a quadruple-emitter, and

FIGS. 2, 3, 4 and 5 show various examples of a component with double-emitters.

### DETAILED DESCRIPTION

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

FIG. 1 shows a component 10 comprising a quadruple-emitter C. The quadruple-emitter C has four ridges R. Different ridges R may be configured to generate electromagnetic radiation of different wavelengths. Also, it is possible that the different ridges R are configured for generating electromagnetic radiations of substantially the same peak wavelength. For example, the ridges are configured to generate laser radiation. Such a component or quadruple-emitter may have a high yield loss, since all four emitter regions R are in spec and in sum should have, for example, a predetermined desired wavelength broadening of about 10 nm. High effort is therefore required to achieve the four different wavelengths on a quadruple-emitter.

According to FIG. 1, the component 10 or the quadruple-emitter C has four connection pads AP, in particular on a chip rear side, which are each configured for electrical contacting, for example for n- or p-contacting of one of the ridges R. Along the lateral direction, the ridges R are laterally spaced from each other, for example by a lateral distance A of about 50 μm in each case. The component 10 or the quadruple-emitter C has a lateral width B of, for example, 300 μm.

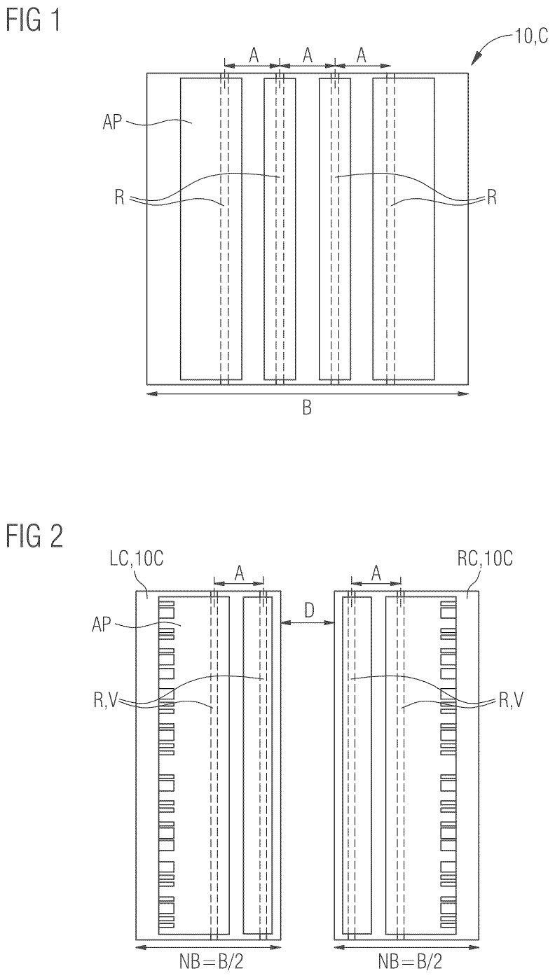

According to FIG. 2, the component 10 has two double-emitters LC and RC or two separate semiconductor chips 10C. The semiconductor chips 10C are spatially spaced from each other along the lateral direction by an intermediate region D or by a lateral distance D.

In particular, the quadruple-emitter C shown in FIG. 1 can be split into two double-emitters LC and RC. The lateral width B is halved, while the lateral distance A between the ridges R can be maintained. In this case, only two instead of four emitter regions R, i.e., two ridges R instead of four ridges R, should be in spec. This leads to a significantly higher yield, since one emitter region at most is shifted in wavelength. It therefore requires significantly less effort in fabricating the individual double-emitters LC and RC. Each of the individual double-emitters LC and RC can be formed as a single semiconductor chip 10C. Since the lateral distance D between the semiconductor chips 10C can be selected variably, a desired bandwidth broadening can be achieved in a simple manner.

Compared to FIG. 1, FIG. 2 thus shows two double-emitters LC and RC, in particular two separate semiconductor chips 10C, instead of a single quadruple-emitter C. The fabrication of the separate double-emitters LC and RC is simplified since no artificial trench is created, for example in the quadruple-emitter C, to widen the bandwidth. Compared to the quadruple-emitter C shown in FIG. 1, the separated semiconductor chips 10C each have a lateral width NB that is half the lateral width of the quadruple-emitter C shown in FIG. 1.

As shown schematically in FIG. 2, each of the double-emitters LC and RC can have several through-contacts V. In particular, the through-contacts V are each formed to make electrical contact with one of the ridges R. For example, the through-contacts V extend along the entire lateral extent of the associated ridges R. The number of through-contacts V is, for example, identical to the number of connection pads AP and/or the number of ridges R. In other words, for each ridge R, there is a through-contact V and/or a connection pad AP uniquely assigned to it.

The semiconductor chip 10C may include a first semiconductor layer, a second semiconductor layer, and an active region disposed between the first semiconductor layer and the second semiconductor layer, wherein the active region is configured to generate electromagnetic radiation, in particular coherent electromagnetic radiation, during operation of the semiconductor chip 10C. In a top view of the semiconductor chip 10C, the through-contact V may overlap with a subregion of the active zone. Due to the overlap, electromagnetic radiation is mainly generated in particular only in the subregion of the active zone overlapping with the through-contact V.

If the semiconductor chip 10C has two ridges R that are electrically contacted via two associated through-contacts V and two associated connection pads AP, the semiconductor chip 10C can generate electromagnetic radiations in two different subregions of the active zone. The generated electromagnetic radiations are, for example, laser radiations. In particular, the generated laser radiations have substantially the same peak wavelength. The laser radiations S may be coupled out at a side surface of the semiconductor chip 10C. This is shown schematically, for example, in FIG. 5.

The component 10 shown in FIG. 2 has two semiconductor chips 10C, each having two emitter regions R whose lateral distance is A. For example, the lateral distance A is indicated by the distance between two emission points of the two emitter regions on a side surface of the semiconductor chip 10C or on a side surface of the component 10. For example, the lateral distance A is from 20 μm to 60 μm, for instance 25 μm±5 μm, 30 μm±5 μm, 35 μm±5 μm, or 50 μm±5 μm. If the component 10 has two or more semiconductor chips 10C, the semiconductor chips 10 may have the same lateral distance A between adjacent ones in emitter regions R.

In particular, the component 10 has exactly two semiconductor chips 10C, each of which is formed as a double-emitter LC or RC with exactly two emitter regions R. Deviating from FIG. 2, wherein the semiconductor chips 10C are each formed as double-emitters, the semiconductor chips 10C can each be formed as triple-emitter with exactly three emitter regions R. The emitter regions R of the same semiconductor chip 10C or of all radiation-emitting semiconductor chips 10C of the component 10 may be configured to generate coherent radiation of the same peak wavelength or of different peak wavelengths.

It is possible for the component 10 to have two, three, or more semiconductor chips 10C that are different from each other or of the same structure. If the semiconductor chips 10C are formed in a similar manner, they may have the same semiconductor structure. It is possible that the semiconductor bodies of the similarly formed semiconductor chips 10C are formed from the same materials. For example, the semiconductor bodies of the semiconductor chips 10C shown in FIG. 2 may be formed from a common semiconductor body of a semiconductor chip 10C shown in FIG. 1, for example, by a singulation process. Also, the semiconductor chips 10C may each have the same number of emitter regions R. If the semiconductor chips 10C are formed differently from each other, the semiconductor chips 10C may have different numbers of emitter regions R and/or different semiconductor structures, or be formed from different semiconductor materials.

As schematically shown in FIG. 1 or 2, the emitter regions R of the same semiconductor chip 10C extend parallel to each other. The emitter regions R of the same semiconductor chip 10C are spaced apart from each other by a lateral distance A, wherein the lateral distance A may be from 20 μm to 60 μm. For example, the lateral distance A is 30 μm or 50 μm.

The two semiconductor chips 10C are spatially spaced apart from each other by a lateral intermediate region D or by a lateral distance D. The lateral intermediate region D may be from 5 μm to 50 μm wide. The lateral distance D between two adjacent semiconductor chips 10C may be larger or smaller than the lateral distance A between two adjacent emitter regions R. In particular, the intermediate region D between two adjacent semiconductor chips 10C is configured to adjust a lateral distance between two outer adjacent emitter regions R of the adjacent semiconductor chips 10C.

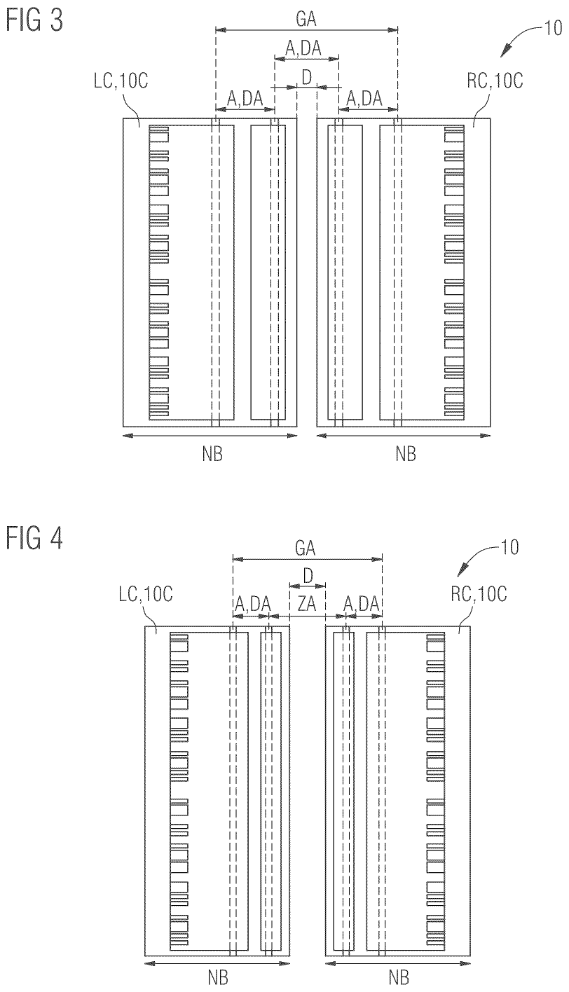

It is possible for the component 10 to have an equidistant lateral separation distance DA for all emitter regions R. This is shown schematically in FIG. 3, for example. In this case, two adjacent emitter regions R of the same semiconductor chip 10C or of different semiconductor chips 10 have the same lateral separation distance DA, in particular up to manufacturing tolerances of a few nanometers, such as of at most 5 nm, 3 nm or 1 nm. In other words, any two adjacent emitter regions R of the component may have the same separation distance DA. For example, the equidistant separation distance DA is 30 μm±5 μm, 35 μm±5 μm, 40 μm±5 μm, 45 μm±5 μm, or 50 μm±5 μm.

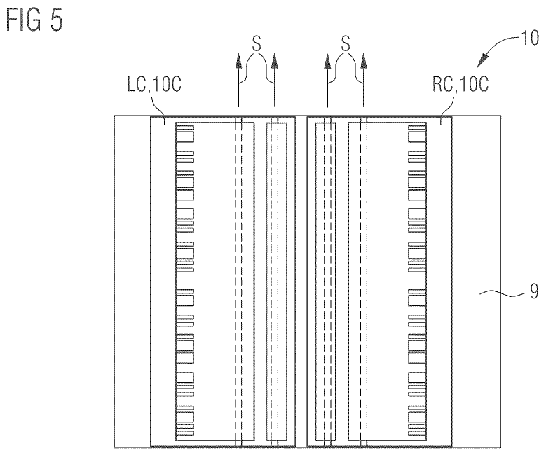

The embodiments of a component shown in FIGS. 3 and 4 are substantially the same as the embodiment of a component shown in FIG. 2.

According to FIG. 3, the lateral spacing A or the equidistant lateral separation distance DA may be 50 μm. The intermediate region D between the two adjacent semiconductor chips 10C may be 5 μm wide. If the component 10 has two semiconductor chips 10C with a total of four emitter regions R, the four emitter regions R may be distributed over a total lateral width GA of for instance 150 μm. Thus, the total width GA indicates the width of a region wherein the emitter regions R, in particular all of the emitter regions R, of the component 10 are located. Each of the semiconductor chips 10C may have a lateral width NB of for instance 150 μm. All of the geometric dimensions specified in this disclosure with respect to width and/or spacing may be subject to manufacturing tolerances of a few microns, for instance of no more than 5 μm, 3 μm, 2 μm, or 1 μm.

According to FIG. 3, n ridges R of a semiconductor chip C or of a laser diode shown for example in FIG. 1 are divided into groups of n/2 ridges R each on two separate semiconductor chips/laser diodes 10C. In particular, an equidistant separation distance DA for all n ridges R of both separate semiconductor chips/laser diodes is shown, especially after being mounted on a carrier/substrate 9 (see also FIG. 5). The number n of ridge R can also be 6, in deviation from 4.

According to FIG. 4, the semiconductor chips 10C each have the same lateral distance A between the emitter regions R associated with the respective semiconductor chip 10C. Two adjacent emitter regions R of different semiconductor chips 10C are spatially spaced apart from each other by a lateral intermediate distance ZA, wherein the lateral intermediate distance ZA between two adjacent emitter regions R of different semiconductor chips 10C is different from the lateral distance A between two adjacent emitter regions R of the same semiconductor chip 10C. For example, the lateral intermediate distance ZA between the two adjacent emitter regions R of different semiconductor chips 10C is larger or smaller than the lateral distance A between two adjacent emitter regions R of the same semiconductor chip 10C.

Referring to FIG. 4, the component 10 has a lateral distance A between two adjacent emitter regions R of the same semiconductor chip 10C, which may be 30 μm. The lateral intermediate distance ZA between two adjacent emitter regions R of adjacent semiconductor chips 10C may be 70 μm. The intermediate region D may be 45 μm wide. The total width GA over which the four emitter regions R are distributed may further be for instance 150 μm. Each of the semiconductor chips 10C may have a lateral NB of about 150 μm.

According to FIG. 4, n ridges R of a semiconductor chip C or a laser diode shown for example in FIG. 1 are divided into groups of n/2 ridges R each on two separate semiconductor chips/laser diodes 10C. The lateral distance of the respective outer ridges R is maintained (e.g. GA=150 μm). In contrast to FIG. 3, the respective inner ridges R are moved closer to the outer ridges (e.g. distance A=30 μm) to achieve more space between the two semiconductor chips/laser diodes 10C.

In particular, FIGS. 3 and 4 show concrete realizations of a component 10 comprising two double-emitters LC and RC with 10 nm bandwidth. However, the details of the component 10 described herein are not necessarily limited to those given in FIGS. 3 and 4.

Deviating from FIGS. 2-4, the double-emitters LC and RC can be arranged on a carrier 9, in particular on a common carrier 9 (cf. for example FIG. 5). Further deviating from FIGS. 2-4, the component 10 may have for example two triple-emitters or even two quadruple-emitters. The emitters, i.e. the semiconductor chips 10C, can be fixed, in particular soldered, on a carrier 10 in such a way that a predetermined distance A or D between the emitter regions R, i.e. between the ridges R, or between the emitters or between the semiconductor chips 10C can be maintained up to manufacturing tolerances of, for example, +/−5 μm or +/−2 μm. The distance A between the ridges R can be around 50 μm or smaller. With the combination of the individual, separate double-emitters or triple-emitters, a wavelength broadening of for instance 10 nm+/−5 nm, 10 nm+/−3 nm or 10 nm+/−1 nm can be achieved.

For example, for achieving the increase in the width of the spectral emission, it is to superimpose spectra of individual ridges R with a small wavelength offset. Often a spectral width (wavelength broadening) of about 10 nm (FWHM) is desirable. To achieve this value, the wavelength offset between emitters or between emitter regions or between ridges can be about 2 μm-5 μm between individual resonators.

The component 10 may include a plurality of resonators, wherein the rigdes are arranged adjacent to each other such that spectra of individual ridges R are superimposed at a wavelength offset during operation of the component 10. In particular, the wavelength offset is from 2 μm to 5 μm between individual resonators. As a result, a spectral width of 10 nm+/−5 nm can be achieved.

FIG. 5 shows a component 10 with the at least two semiconductor chips 10C on a common carrier 9. The semiconductor chips 10C can be electrically externally connected via the carrier 9, in particular via a contact structure of the carrier 9. The contact structure of the carrier 9 may be adapted to the arrangement of the connection pads AP on the rear sides of the semiconductor chip 10C, or vice versa.

The number of connection pads AP of a semiconductor chip 10C may be identical to the number of emitter regions R of the corresponding semiconductor chip 10C. In particular, the emitter regions R are formed as ridges. The semiconductor chips 10C may have through-contacts V, each of which is formed to make electrical contact with one of the ridges R. The through-contacts V may extend along the entire lateral extent of the associated ridges R. In particular, the positions of the through-contact contacts V define selected subregions of the active region of the respective semiconductor chip 10C, into which charge carriers are selectively injected, such that the selected subregions of the active region are configured to generate electromagnetic radiation during operation of the component 10. For example, the number of through-contacts V is identical to the number of connection pads AP and/or the number of ridges R.

In operation of the component 10, the emitter regions R are configured to generate electromagnetic radiation that can be laterally coupled out from the component 10 at a side surface of the component 10, i.e., at side surfaces of the semiconductor chips 10C. For example, the emitter regions R are arranged adjacent to each other such that a wavelength broadening of 10 nm+/−5 nm is achieved.

In particular, by using double-emitters, the natural shift, especially a desired bandwidth widening, of the wavelength of an emitter region/ridge R per semiconductor chip 10C, such as per laser diode LC or RC, can be achieved. In particular, the natural shift of the wavelength arises from the short, predetermined distance of the emitter region/ridges R from the chip edge. The present disclosure thus provides a simpler method to achieve the desired bandwidth broadening, as compared to a quadruple-emitter with elaborate shifting of the wavelength by etched trenches.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1. A component having a carrier and exactly two semiconductor chips which are arranged next to one another on the carrier and are each formed as a double-emitter with exactly two emitter regions or each as a triple-emitter with exactly three emitter regions and are thus different from a single-emitter, wherein
the emitter regions of the component are assigned to exactly the two semiconductor chips,
the exactly two semiconductor chips are laser diodes having respective ridges, the ridges defining the emitter regions, and
the exactly two semiconductor chips are electrically contacted via the carrier.

2. The component according to claim 1,
wherein the exactly two semiconductor chips are each formed as double-emitters with exactly two emitter regions.

3. The component according to claim 1,
wherein the exactly two semiconductor chips are each formed as triple-emitters with exactly three emitter regions.

4. The component according to claim 1, wherein the emitter regions are each configured to generate coherent radiation.

5. The component according to claim 1, wherein the exactly two semiconductor chips have the same structure.

6. The component according to claim 1, wherein the emitter regions of the same semiconductor chip are parallel to each other and are spatially spaced apart by a lateral distance, the lateral distance being from 20 μm to 60 μm.

7. The component according to claim 1, wherein the exactly two semiconductor chips are spatially spaced apart from each other by a lateral intermediate region, the lateral intermediate region being from 5 μm to 50 μm wide.

8. The component according to claim 1, which has an equidistant lateral separation distance for all emitter regions.

9. The component according to claim 1, wherein the exactly two semiconductor chips each have the same lateral distance between the emitter regions associated with the respective semiconductor chip, wherein
two adjacent emitter regions of different semiconductor chips are spatially spaced apart from each other by an intermediate distance, and
the lateral intermediate distance between the two adjacent emitter regions of different semiconductor chips is different from the lateral distance between two adjacent emitter regions of the same semiconductor chip.

10. The component according to claim 9,
wherein the lateral intermediate distance between the two adjacent emitter regions of different semiconductor chips is greater than the lateral distance between the two adjacent emitter regions of the same semiconductor chip.

11. The component according to claim 1, wherein the exactly two semiconductor chips each have connection pads, the exactly two semiconductor chips being electrically conductively connected to a contact structure of the carrier via the connection pads.

12. The component according to claim 11,
wherein the number of connection pads of a semiconductor chip is equal to the number of the emitter regions of the associated semiconductor chip.

13. The component according to claim 11, wherein
the semiconductor chips have through-contacts, each of which is formed to make electrical contact with one of the ridges,
the through-contacts extend along the entire lateral extent of the associated ridges, and
the number of through-contacts is identical to the number of connection pads and/or the number of ridges.

14. The component according to claim 1, wherein the emitter regions are arranged next to each other in such a way that a wavelength broadening of 10 nm+/−5 nm is achieved.

15. The component according to claim 1, which comprises a plurality of resonators, wherein the emitter regions are arranged next to each other such that, in operation of the component, spectra of individual emitter regions are superimposed with a wavelength offset that is from 2 μm to 5 μm between the individual resonators, thereby achieving a spectral width of 10 nm+/−5 nm.

16. An AR, VR or data glasses comprising the component according to claim 1.
